(19) United States
(12) Patent Application Publication
(10) Pub. No.: US 2025/0065746 A1
(43) Pub. Date: Feb. 27, 2025

(54) DRY CONTACT-BASED AUTOMATIC ALIGNMENT OF ELECTRIC VEHICLE (EV) CHARGING LOAD TO WHOLE CIRCUIT CONSUMPTION

(71) Applicant: Siemens Industry, Inc., Alpharetta, GA (US)

(72) Inventors: Daniel Feldman, New York, NY (US); Justin Michael Cardwell, Cumming, GA (US); Hector Malacara, Alpharetta, GA (US); Nezar Alattar, Buford, GA (US); Weston Sheldon, Columbus, GA (US)

(73) Assignee: Siemens Industry, Inc., Alpharetta, GA (US)

(21) Appl. No.: 18/455,687

(22) Filed: Aug. 25, 2023

(51) Int. Cl. B60L 53/62; B60L 53/30; H02H 3/093; H02J 7/00

(52) U.S. Cl. CPC B60L 53/62; B60L 53/305; H02H 3/0935; H02J 7/0071

(57) ABSTRACT

A system for dry contact-based automatic alignment of electric vehicle (EV) charging load to whole circuit consumption comprises an electric vehicle supply equipment (EVSE) including a charger relay circuit, a dry contact input and a current transformer (CT) clamp that is installed on an external electrical circuit to be measured against. The CT clamp outputs a signal that can be calibrated to generate an analog signal that passes a minimum threshold of the dry contact input. Normally the inputs at the dry contact input in the EVSE are programmed. A logic behind the external electrical circuit is modified to: a) turn off delivery of power to the EV when a calibrated current on the CT clamp is exceeded b) turn back on power to the EV if the calibrated current is no longer exceeded for over X seconds.

### BACKGROUND

### 1. Field

Aspects of the present invention generally relate to a system for dry contact-based automatic alignment of electric vehicle (EV) charging load to whole circuit consumption.

### 2. Description of the Related Art

Either for safety or power contract reasons, it is commonly necessary for Electric Vehicle (EV) chargers to be deployed in locations in which there is a fixed current/power budget to be shared between an EV charger and either the rest of the building or the rest of the circuit in which the EV charger is installed.

In these situations, existing solutions invariably require either adding an additional meter that transmits the consumption of the related circuit to an Electric vehicle supply equipment (EVSE) (which is expensive), or for the EVSE to communicate digitally directly to a building meter (which may not be possible depending on the location). An alternative solution for the EVSE to be built with an additional accurate meter that measures the circuit current, a solution that is also potentially expensive.

Therefore, a system is then needed for dry contact-based automatic alignment of electric vehicle (EV) charging load to whole circuit consumption.

### SUMMARY

Briefly described, aspects of the present invention relate to a system for dry contact-based automatic alignment of electric vehicle (EV) charging load to whole circuit consumption. This invention does not require an additional internal or external accurate current meter, which is a more expensive solution.

In accordance with one illustrative embodiment of the present invention, a system is provided. It comprises an electric vehicle supply equipment (EVSE) including a charger relay circuit and a dry contact input to receive inputs. The system further comprises a current transformer (CT) clamp that is installed on an external electrical circuit to be measured against. The CT clamp outputs a signal that can be calibrated to generate an analog signal that passes a minimum threshold of the dry contact input. Normally the inputs at the dry contact input in the EVSE are programmed to serve a safety bypass of the EVSE that allows the external electrical circuit to shutdown the charger relay circuit, requiring plugging and unplugging an electric vehicle (EV) to restart charging. A logic behind the external electrical circuit is modified to: a) turn off delivery of power to the EV when a calibrated current on the CT clamp is exceeded b) turn back on power to the EV if the calibrated current is no longer exceeded for over X seconds.

In accordance with one illustrative embodiment of the present invention. a system is provided. It comprises an electric vehicle supply equipment (EVSE) including a charger relay circuit and a dry contact input to receive inputs. The system further comprises a current transformer (CT) clamp that is installed on an external electrical circuit to be measured against. To ensure a continuity of operation, a two-step approach can be used: a) a large-step-down, b) an adaptable-step-up. In a modified algorithm, instead of closing a relay, the EVSE reduces a current by a large step and then verifies whether the dry contact input still indicates a reduction is needed. If a further reduction is needed, then an additional large step is performed, wherein a size of the additional large step is determined depending on a maximum charger current and local regulation for how long an overcurrent protection device needs to turn current off. A different, smaller step down could be chosen depending on a jurisdiction and the EVSE. After a step down triggered by a change in rest-of-building consumption, the EVSE waits always configurable X seconds before attempting a step up. The adaptable-step-up works in a discovery mode, to try to maximize the current allocated to an EV, slowly and safely. An algorithm starts with a step-up that is 50% of the step-down. If there is an indication from the CT of overload in less than X seconds from the step-up, the step-up value is changed to 50% of the previous step-up value. An adjustment exercise continues until a dry contact interrupt is gone for more than X seconds. At this point, a load is “aligned to a building” and if an alignment to the load of the building is achieved at less than a maximum charger current for Y seconds (configurable value), the EVSE attempts a step-up again, starting from 50% of the step-down value, until a steady state is reached such that the algorithm repeats throughout a charging session.

In accordance with one illustrative embodiment of the present invention, a system is provided for dry contact-based automatic alignment of electric vehicle (EV) charging load to whole circuit consumption. The system comprises:
a) an electrical circuit, to which an electric vehicle supply equipment (EVSE) and rest of a home are connected;
b) a circuit breaker limited to a predetermined amount of current;
c) a current transformer (CT) clamp, which:
   a. is attached to the electrical circuit, and
   b. outputs an analog voltage through a wire proportional to the current passing through the electrical circuit, to reach an adjustable current level that triggers a dry input digital output to be a 1 at a certain current level flowing through the electrical circuit;
   c. has means for an adjustable current setpoint level;
d) a wire connecting between the CT clamp and the dry input on the EVSE;
e) the EVSE with:
   a. a dry input contact with an isolated reading,
   b. an electromechanical relay that can be turned on/off, and
   c. a microcontroller;
f) the microcontroller inside the EVSE that:
   a. senses a dry input isolated output,
   b. is able to advertise a maximum current to the EV while charging through a control pilot (PWM signal), powerline communications, and
   c. is able to shutdown current altogether by controlling the electromechanical relay to be on/off,
   wherein when the EVSE receives a voltage through the dry input contact it indicates that the electrical circuit has reached its maximum rated amperage (over current),
   wherein the EVSE sends a OA command to an EV (or shuts down the electromechanical relay), and
   wherein an over current state is reset if a cable is unplugged from the EV.

In accordance with one illustrative embodiment of the present invention, a system is provided for dry contact-based automatic alignment of electric vehicle (EV) charging load to whole circuit consumption. The system comprises:
a) an electrical circuit, to which an electric vehicle supply equipment (EVSE) and rest of a home are connected;
b) a circuit breaker limited to a predetermined amount of current;
c) a current transformer (CT) clamp, which:
   a. is attached to the electrical circuit, and
   b. outputs an analog voltage through a wire proportional to the current passing through the electrical circuit, to reach an adjustable current level that triggers a dry input digital output to be a 1 at a certain current level flowing through the electrical circuit;
   c. has means for an adjustable current setpoint level;
d) a wire connecting between the CT clamp and the dry input on the EVSE;
e) the EVSE with:
   a. a dry input contact with an isolated reading,
   b. an electromechanical relay that can be turned on/off, and
   c. a microcontroller;
f) the microcontroller inside the EVSE that:
   a. senses a dry input isolated output,
   b. is able to advertise a maximum current to the EV while charging through a control pilot (PWM signal), powerline communications, LIN CP, CAN Bus or other methods, and, and
   c. is able to shutdown current altogether by controlling the electromechanical relay to be on/off,
   wherein the EVSE receives a voltage through the dry input contact and indicates that the electrical circuit has reached its maximum rated amperage (over current), the EVSE reduces an amount of current allocated to the EV by large steps, until the dry input contact input no longer indicates that a maximum current has been reached, and
   wherein, at that point, the EVSE increases the current by a variable amount, smaller than a large step, in attempts to reach a current level that will be as high as possible without triggering an over current indication from the dry input contact.

The above described features and advantages, as well as others, will become more readily apparent to those of ordinary skill in the art by reference to the following detailed description and accompanying drawings. While it would be desirable to provide one or more of these or other advantageous features, the teachings disclosed herein extend to those embodiments which fall within the scope of the appended claims, regardless of whether they accomplish one or more of the above-mentioned advantages.

### BRIEF DESCRIPTION OF THE DRAWINGS

For a more complete understanding of the present disclosure, and the advantages thereof, reference is now made to the following descriptions taken in conjunction with the accompanying drawings, wherein like numbers designate like objects.

FIG. 1 illustrates a system for dry contact-based automatic alignment of electric vehicle (EV) charging load to whole circuit consumption in accordance with an embodiment of the present invention.

FIG. 2 illustrates four algorithms of four different embodiments as a substitute to the algorithm in FIG. 1 in accordance with an embodiment of the present invention.

### DETAILED DESCRIPTION

Various technologies that pertain to systems and methods that provide a system for dry contact-based automatic alignment of electric vehicle (EV) charging load to whole circuit consumption are presented. The drawings discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged apparatus. It is to be understood that functionality that is described as being carried out by certain system elements may be performed by multiple elements. Similarly, for instance, an element may be configured to perform functionality that is described as being carried out by multiple elements. The numerous innovative teachings of the present application will be described with reference to exemplary non-limiting embodiments.

To facilitate an understanding of embodiments, principles, and features of the present invention, they are explained hereinafter with reference to implementation in illustrative embodiments. In particular, they are described in the context a system for dry contact-based automatic alignment of electric vehicle (EV) charging load to whole circuit consumption. Embodiments of the present invention, however, are not limited to use in the described devices or methods.

The components and materials described hereinafter as making up the various embodiments are intended to be illustrative and not restrictive. Many suitable components and materials that would perform the same or a similar function as the materials described herein are intended to be embraced within the scope of embodiments of the present invention.

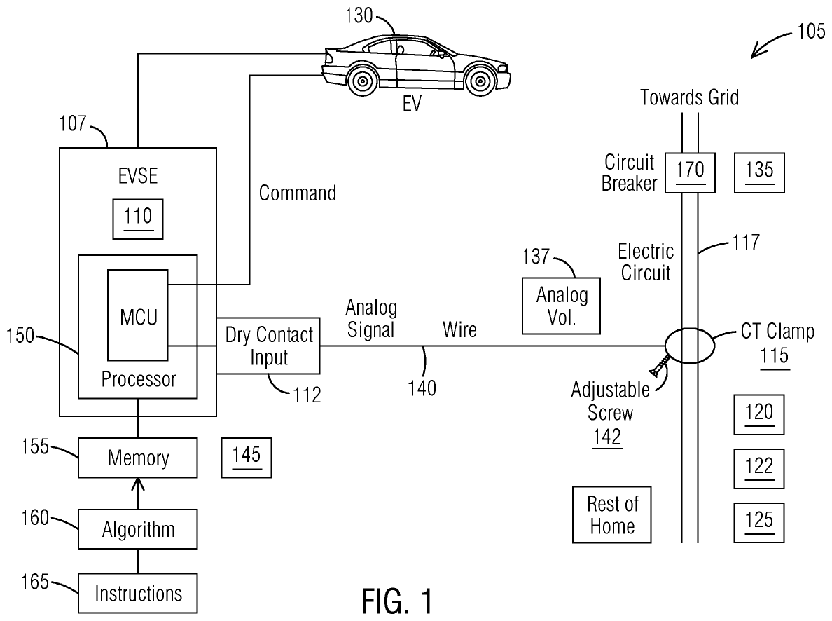

These and other embodiments of the system are provided for providing a system for dry contact-based automatic alignment of electric vehicle (EV) charging load to whole circuit consumption according to the present disclosure are described below with reference to FIG. 1 herein. The drawing is not necessarily drawn to scale.

Consistent with an embodiment of the present invention, FIG. 1 represents a system 105 for dry contact-based automatic alignment of electric vehicle (EV) charging load to whole circuit consumption in accordance with an embodiment of the present invention. The system 105 comprises an electric vehicle supply equipment (EVSE) 107 including a charger relay circuit 110 and a dry contact input 112 to receive inputs. The system 105 further comprises a current transformer (CT) clamp 115 that is installed on an external electrical circuit 117 to be measured against. The CT clamp 115 outputs a signal 120 that can be calibrated to generate an analog signal 122 that passes a minimum threshold 125 of the dry contact input 112.

Normally the inputs at the dry contact input 112 in the EVSE 107 are programmed to serve a safety bypass of the EVSE 107 that allows the external electrical circuit 117 to shutdown the charger relay circuit 110. requiring plugging and unplugging an electric vehicle (EV) 130 to restart charging. A logic 135 behind the external electrical circuit 117 is modified to: a) turn off delivery of power to the EV 130 when a calibrated current on the CT clamp 115 is exceeded b) turn back on power to the EV 130 if the calibrated current is no longer exceeded for over X seconds.

In the system 105. the X seconds is a programmable value. A large enough threshold is important to prevent situations of motorboating. The CT clamp 115 outputs an analog voltage 137 through a wire 140 proportional to a current passing through the external electrical circuit 117. The CT clamp 115 can be adjusted in amplitude with a screw 142, to reach a voltage that triggers a dry input digital output 145 to be a 1 at a certain current level flowing through the circuit 117, e.g., 200A. The screw 142 on the current transformer 115 adjusts the setpoint current value at which the FET in the CT to change state from 0 to 1. If we set the screw for full range of 200 amps the FET within the CT will not send a 1 signal until the current passing through the CT reached that current level of 200 amps. The screw 142 adjustments equates to when the charger will start going through the throttling logic. The screw 142 can be a part of a current monitoring device with an adjustable means for setting a threshold or has a “means for adjusting current.” The screw 142 sets a setpoint of when it starts throttling (adjustable setpoint or threshold). To monitor over-current. turn a setpoint screw counterclockwise until a status close LED turns on. Then, slowly turn the setpoint screw clockwise until the status open LED just turns on. Turn the setpoint screw an additional ¼ turn clockwise for operational margin. The system 105 further comprises a processor 150 coupled to a memory 155 storing an algorithm 160 with instructions 165 to carry out the steps of the above process for dry contact-based automatic alignment of electric vehicle (EV) charging load to whole circuit consumption. The system further comprises a circuit breaker 170 limited to a predetermined amount of current.

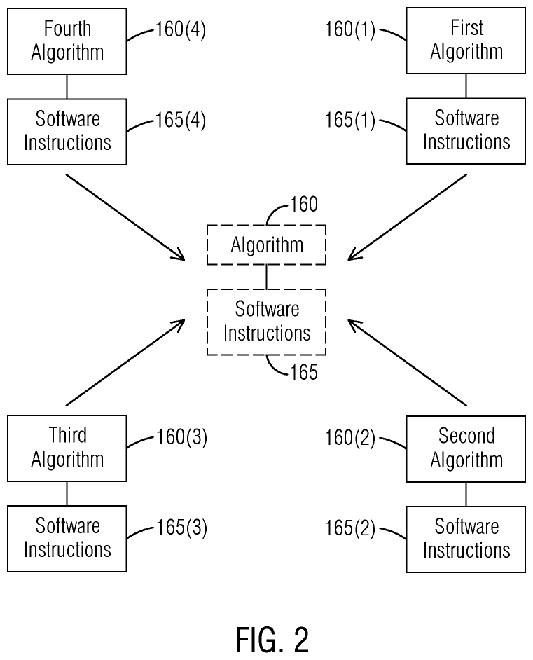

Referring to FIG. 2. it illustrates four algorithms of four different embodiments as a substitute to the algorithm in FIG. 1 in accordance with an embodiment of the present invention. In a first embodiment, the system 105 further comprises a processor coupled to a memory storing the algorithm 160 as a first algorithm 160(1) with instructions 165(1) to carry out the steps of the above process for dry contact-based automatic alignment of electric vehicle (EV) charging load to whole circuit consumption. In a second embodiment the algorithm 160 is a second modified algorithm 160(2) with software instructions 165(2) to carry out the steps of this process using a processor, for dry contact-based automatic alignment of electric vehicle (EV) charging load to whole circuit consumption. In a third embodiment the microcontroller inside the EVSE is coupled to a memory storing the algorithm 160 as a third algorithm 160(3) with software instructions 165(3) to carry out the steps of this process for dry contact-based automatic alignment of electric vehicle (EV) charging load to whole circuit consumption. In a fourth embodiment the microcontroller inside the EVSE is coupled to a memory storing a fourth algorithm 160(4) with software instructions 165(4) to carry out the steps of this process for dry contact-based automatic alignment of electric vehicle (EV) charging load to whole circuit consumption.

In another exemplary system, it comprises an electric vehicle supply equipment (EVSE) including a charger relay circuit and a dry contact input to receive inputs. The system further comprises a current transformer (CT) clamp that is installed on an external electrical circuit to be measured against. To ensure a continuity of operation, a two-step approach can be used: a) a large-step-down. b) an adaptable-step-up. In a second modified algorithm 160(2) with software instructions 165(2) to carry out the steps of this process using a processor, for dry contact-based automatic alignment of electric vehicle (EV) charging load to whole circuit consumption, instead of closing a relay. the EVSE reduces a current by a large step and then verifies whether the dry contact input still indicates a reduction is needed. If a further reduction is needed, then an additional large step is performed, wherein a size of the additional large step is determined depending on a maximum charger current and local regulation for how long an overcurrent protection device needs to turn current off. A different, smaller step down could be chosen depending on a jurisdiction and the EVSE. After a step down triggered by a change in rest-of-building consumption, the EVSE waits always configurable X seconds before attempting a step up.

The adaptable-step-up works in a discovery mode, to try to maximize the current allocated to an EV. slowly and safely. An algorithm as part of the second algorithm 160(2) starts with a step-up that is 50% of the step-down. If there is an indication from the CT of overload in less than X seconds from the step-up, the step-up value is changed to 50% of the previous step-up value. An adjustment exercise continues until a dry contact interrupt is gone for more than X seconds. At this point, a load is “aligned to a building” and if an alignment to the load of the building is achieved at less than a maximum charger current for Y seconds (configurable value), the EVSE attempts a step-up again, starting from 50% of the step-down value, until a steady state is reached such that the algorithm repeats throughout a charging session.

If an AC charger can deliver 40A per phase, a 10A step-down guarantees that the AC charger will inform the EV to reduce current through a control pilot within less than 5 seconds, if it waits for results of a command to the EV to reduce current for 1 second. In the example of the 10A step-down, a 5A step-up would be a first attempt. A 5A step-down could be chosen for a 32A EVSE. If a 5A initial step-up would trigger a dry contact interrupt, a current would be reduced by 3A.

In another exemplary system, it comprises an electrical circuit, to which an electric vehicle supply equipment (EVSE) and rest of a home are connected. The system further comprises a circuit breaker limited to a predetermined amount of current and a current transformer (CT) clamp, which: is attached to the electrical circuit, and outputs an analog voltage through a wire proportional to the current passing through the electrical circuit. and can be adjusted in amplitude with a screw. to reach a voltage that triggers a dry input digital output to be a I at a certain current level flowing through the electrical circuit.

The system further comprises a wire connecting between the CT clamp and the dry input on the EVSE and the EVSE with: a dry input contact with an isolated reading, an electromechanical relay that can be turned on/off. and a microcontroller. The microcontroller inside the EVSE, coupled to a memory storing a third algorithm 160(3) with software instructions 165(3) to carry out the steps of this process for dry contact-based automatic alignment of electric vehicle (EV) charging load to whole circuit consumption that: senses a dry input isolated output, is able to advertise a maximum current to the EV while charging through a control pilot (PWM signal), powerline communications, and is able to shutdown current altogether by controlling the electromechanical relay to be on/off.

When the EVSE receives a voltage through the dry input contact it indicates that the electrical circuit has reached its maximum rated amperage (over current). The EVSE sends a 0A command to an EV (or shuts down the electromechanical relay), and an over current state is reset if a cable is unplugged from the EV.

The circuit breaker is limited to the predetermined amount of current of 200A. To reach the voltage that triggers the dry input digital output to be a 1 at a certain current level of 200A flowing through the electrical circuit. The dry input contact with the isolated reading (input is analog, output is digital, can be 0 or 1). The microcontroller senses a dry input isolated output (0 or 1).

In another exemplary system, it comprises an electrical circuit, to which an electric vehicle supply equipment (EVSE) and rest of a home are connected, a circuit breaker limited to a predetermined amount of current and a current transformer (CT) clamp, which: is attached to the electrical circuit, and outputs an analog voltage through a wire proportional to the current passing through the electrical circuit, and can be adjusted in amplitude with a screw, to reach a voltage that triggers a dry input digital output to be a 1 at a certain current level flowing through the electrical circuit.

The system further comprises a wire connecting between the CT clamp and the dry input on the EVSE, the EVSE with: a dry input contact with an isolated reading, an electromechanical relay that can be turned on/off, and a microcontroller. The microcontroller inside the EVSE, coupled to a memory storing a fourth algorithm 160(4) with software instructions 165(4) to carry out the steps of this process for dry contact-based automatic alignment of electric vehicle (EV) charging load to whole circuit consumption that: senses a dry input isolated output, is able to advertise a maximum current to the EV while charging through a control pilot (PWM signal), powerline communications, and is able to shutdown current altogether by controlling the electromechanical relay to be on/off.

The EVSE receives a voltage through the dry input contact and indicates that the electrical circuit has reached its maximum rated amperage (over current), the EVSE reduces an amount of current allocated to the EV by large steps. until the dry input contact input no longer indicates that a maximum current has been reached. At that point, the EVSE increases the current by a variable amount, smaller than a large step, in attempts to reach a current level that will be as high as possible without triggering an over current indication from the dry input contact.

The circuit breaker is limited to the predetermined amount of current of 200A. To reach the voltage that triggers the dry input digital output to be a 1 at a certain current level of 200A flowing through the electrical circuit. The dry input contact with the isolated reading (input is analog. output is digital, can be 0 or 1). The microcontroller senses a dry input isolated output (0 or 1).

While a system that does not require an additional internal or an external accurate current meter is described here a range of one or more other systems are also contemplated by the present invention. For example, other systems may be implemented based on one or more features presented above without deviating from the spirit of the present invention.

The techniques described herein can be particularly useful for a Dry Contact input that exists in an EV charger and a CT clamp that is installed on a circuit to be measured against. While particular embodiments are described in terms of a Dry Contact input and a CT clamp, the techniques described herein are not limited to such a system but can also be used with other types of systems.

While embodiments of the present invention have been disclosed in exemplary forms, it will be apparent to those skilled in the art that many modifications, additions, and deletions can be made therein without departing from the spirit and scope of the invention and its equivalents, as set forth in the following claims.

Embodiments and the various features and advantageous details thereof are explained more fully with reference to the non-limiting embodiments that are illustrated in the accompanying drawings and detailed in the following description. Descriptions of well-known starting materials, processing techniques, components and equipment are omitted so as not to unnecessarily obscure embodiments in detail. It should be understood, however, that the detailed description and the specific examples, while indicating preferred embodiments, are given by way of illustration only and not by way of limitation. Various substitutions, modifications, additions and/or rearrangements within the spirit and/or scope of the underlying inventive concept will become apparent to those skilled in the art from this disclosure.

As used herein, the terms “comprises,” “comprising.” “includes,” “including,” “has,” “having” or any other variation thereof, are intended to cover a non-exclusive inclusion. For example, a process, article, or apparatus that comprises a list of elements is not necessarily limited to only those elements but may include other elements not expressly listed or inherent to such process, article, or apparatus.

Additionally, any examples or illustrations given herein are not to be regarded in any way as restrictions on, limits to, or express definitions of, any term or terms with which they are utilized. Instead, these examples or illustrations are to be regarded as being described with respect to one particular embodiment and as illustrative only. Those of ordinary skill in the art will appreciate that any term or terms with which these examples or illustrations are utilized will encompass other embodiments which may or may not be given therewith or elsewhere in the specification and all such embodiments are intended to be included within the scope of that term or terms.

In the foregoing specification, the invention has been described with reference to specific embodiments. However, one of ordinary skill in the art appreciates that various modifications and changes can be made without departing from the scope of the invention. Accordingly, the specification and figures are to be regarded in an illustrative rather than a restrictive sense, and all such modifications are intended to be included within the scope of invention.

Although the invention has been described with respect to specific embodiments thereof, these embodiments are merely illustrative. and not restrictive of the invention. The description herein of illustrated embodiments of the invention is not intended to be exhaustive or to limit the invention to the precise forms disclosed herein (and in particular, the inclusion of any particular embodiment, feature or function is not intended to limit the scope of the invention to such embodiment, feature or function). Rather, the description is intended to describe illustrative embodiments, features and functions in order to provide a person of ordinary skill in the art context to understand the invention without limiting the invention to any particularly described embodiment, feature or function. While specific embodiments of, and examples for, the invention are described herein for illustrative purposes only, various equivalent modifications are possible within the spirit and scope of the invention, as those skilled in the relevant art will recognize and appreciate. As indicated, these modifications may be made to the invention in light of the foregoing description of illustrated embodiments of the invention and are to be included within the spirit and scope of the invention. Thus, while the invention has been described herein with reference to particular embodiments thereof, a latitude of modification, various changes and substitutions are intended in the foregoing disclosures. and it will be appreciated that in some instances some features of embodiments of the invention will be employed without a corresponding use of other features without departing from the scope and spirit of the invention as set forth. Therefore. many modifications may be made to adapt a particular situation or material to the essential scope and spirit of the invention.

Respective appearances of the phrases “in one embodiment,” “in an embodiment,” or “in a specific embodiment” or similar terminology in various places throughout this specification necessarily referring to the same embodiment. Furthermore, the particular features, structures, or characteristics of any particular embodiment may be combined in any suitable manner with one or more other embodiments. It is to be understood that other variations and modifications of the embodiments described and illustrated herein are possible in light of the teachings herein and are to be considered as part of the spirit and scope of the invention.

In the description herein, numerous specific details are provided, such as examples of components and/or methods, to provide a thorough understanding of embodiments of the invention. One skilled in the relevant art will recognize, however, that an embodiment may be able to be practiced without one or more of the specific details, or with other apparatus, systems, assemblies, methods, components, materials, parts, and/or the like. In other instances, well-known structures, components, systems, materials, or operations are not specifically shown or described in detail to avoid obscuring aspects of embodiments of the invention. While the invention may be illustrated by using a particular embodiment, this is not and does not limit the invention to any particular embodiment and a person of ordinary skill in the art will recognize that additional embodiments are readily understandable and are a part of this invention.

It will also be appreciated that one or more of the elements depicted in the drawings/figures can also be implemented in a more separated or integrated manner, or even removed or rendered as inoperable in certain cases, as is useful in accordance with a particular application.

Benefits, other advantages, and solutions to problems have been described above with regard to specific embodiments. However, the benefits, advantages, solutions to problems, and any component(s) that may cause any benefit, advantage, or solution to occur or become more pronounced are not to be construed as a critical, required, or essential feature or component.

What is claimed is:

1. A system comprising:
an electric vehicle supply equipment (EVSE) including a charger relay circuit and a dry contact input to receive inputs;
a current transformer (CT) clamp that is installed on an external electrical circuit to be measured against,
wherein the CT clamp outputs a signal that can be calibrated to generate an analog signal that passes a minimum threshold of the dry contact input,
wherein normally the inputs at the dry contact input in the EVSE are programmed to serve a safety bypass of the EVSE that allows the external electrical circuit to shutdown the charger relay circuit, requiring plugging and unplugging an electric vehicle (EV) to restart charging, and
wherein a logic behind the external electrical circuit is modified to: a) turn off delivery of power to the EV when a calibrated current on the CT clamp is exceeded b) turn back on power to the EV if the calibrated current is no longer exceeded for over X seconds.

2. The system of claim 1, wherein the X seconds is a programmable value.

3. The system of claim 2, wherein a large enough threshold is important to prevent situations of motorboating.

4. The system of claim 1, wherein the CT clamp outputs an analog voltage through a wire proportional to a current passing through the external electrical circuit.

5. The system of claim 4. wherein the CT clamp can be adjusted in amplitude, to reach a voltage that triggers a dry input digital output to be a 1 at a certain current level flowing through the circuit, e.g., 200A.

6. A system comprising:
an electric vehicle supply equipment (EVSE) including a charger relay circuit and a dry contact input to receive inputs;
a current transformer (CT) clamp that is installed on an external electrical circuit to be measured against,
wherein to ensure a continuity of operation, a two-step approach can be used: a) a large-step-down, b) an adaptable-step-up,
wherein in a modified algorithm, instead of closing a relay, the EVSE reduces a current by a large step and then verifies whether the dry contact input still indicates a reduction is needed,
if a further reduction is needed, then an additional large step is performed, wherein a size of the additional large step is determined depending on a maximum charger current and local regulation for how long an overcurrent protection device needs to turn current off
wherein a different, smaller step down could be chosen depending on a jurisdiction and the EVSE,
wherein after a step down triggered by a change in rest-of-building consumption, the EVSE waits always configurable X seconds before attempting a step up,
wherein the adaptable-step-up works in a discovery mode, to try to maximize the current allocated to an EV, slowly and safely,
wherein an algorithm starts with a step-up that is 50% of the step-down,
if there is an indication from the CT of overload in less than X seconds from the step-up, the step-up value is changed to 50% of the previous step-up value,
wherein an adjustment exercise continues until a dry contact interrupt is gone for more than X seconds, and
wherein at this point, a load is “aligned to a building” and if an alignment to the load of the building is achieved at less than a maximum charger current for Y seconds (configurable value), the EVSE attempts a step-up again, starting from 50% of the step-down value, until a steady state is reached such that the algorithm repeats throughout a charging session.

7. The system of claim 6, wherein if an AC charger can deliver 40A per phase, a 10A step-down guarantees that the AC charger will inform the EV to reduce current through a control pilot within less than 5 seconds, if it waits for results of a command to the EV to reduce current for 1 second.

8. The system of claim 7, wherein in the example of the 10A step-down, a 5A step-up would be a first attempt.

9. The system of claim 8, wherein a 5A step-down could be chosen for a 32A EVSE.

10. The system of claim 9, wherein if a 5A initial step-up would trigger a dry contact interrupt, a current would be reduced by 3A.

11. A system for dry contact-based automatic alignment of electric vehicle (EV) charging load to whole circuit consumption, the system comprising:
a) an electrical circuit, to which an electric vehicle supply equipment (EVSE) and rest of a home are connected;
b) a circuit breaker limited to a predetermined amount of current;
c) a current transformer (CT) clamp, which:
a. is attached to the electrical circuit, and
b. outputs an analog voltage through a wire proportional to the current passing through the electrical circuit, and can be adjusted in amplitude, to reach a current level that triggers a dry input digital output to be a 1 at a certain current level flowing through the electrical circuit;
c. has means for an adjustable current setpoint level;
d) a wire connecting between the CT clamp and the dry input on the EVSE;
e) the EVSE with:
a. a dry input contact with an isolated reading,
b. an electromechanical relay that can be turned on/off, and
c. a microcontroller;
f) the microcontroller inside the EVSE that:
a. senses a dry input isolated output,
b. is able to advertise a maximum current to the EV while charging through a control pilot (PWM signal), powerline communications, and
c. is able to shutdown current altogether by controlling the electromechanical relay to be on/off,
wherein when the EVSE receives a voltage through the dry input contact it indicates that the electrical circuit has reached its maximum rated amperage (over current),
wherein the EVSE sends a OA command to an EV (or shuts down the electromechanical relay), and
wherein an over current state is reset if a cable is unplugged from the EV.

12. The system of claim 11, wherein the circuit breaker is limited to the predetermined amount of current.

13. The system of claim 12, wherein to reach the voltage that triggers the dry input digital output to be a 1 at a certain current level of current flowing through the electrical circuit.

14. The system of claim 11. wherein the dry input contact with the isolated reading (input is analog, output is digital, can be 0 or 1).

15. The system of claim 11, wherein the microcontroller senses a dry input isolated output (0 or 1).

16. A system for dry contact-based automatic alignment of electric vehicle (EV) charging load to whole circuit consumption, the system comprising:
a) an electrical circuit, to which an electric vehicle supply equipment (EVSE) and rest of a home are connected;
b) a circuit breaker limited to a predetermined amount of current;
c) a current transformer (CT) clamp, which:
a. is attached to the electrical circuit, and
b. outputs an analog voltage through a wire proportional to the current passing through the electrical circuit, and can be adjusted in amplitude, to reach a current level that triggers a dry input digital output to be a 1 at a certain current level flowing through the electrical circuit;
c. has means for an adjustable current setpoint level;
d) a wire connecting between the CT clamp and the dry input on the EVSE;
e) the EVSE with:
a. a dry input contact with an isolated reading,
b. an electromechanical relay that can be turned on/off, and
c. a microcontroller;
f) the microcontroller inside the EVSE that:
a. senses a dry input isolated output,
b. is able to advertise a maximum current to the EV while charging through a control pilot (PWM signal), powerline communications, and
c. is able to shutdown current altogether by controlling the electromechanical relay to be on/off,
wherein the EVSE receives a voltage through the dry input contact and indicates that the electrical circuit has reached its maximum rated amperage (over current), the EVSE reduces an amount of current allocated to the EV by large steps, until the dry input contact input no longer indicates that a maximum current has been reached, and
wherein, at that point, the EVSE increases the current by a variable amount, smaller than a large step, in attempts to reach a current level that will be as high as possible without triggering an over current indication from the dry input contact.

17. The system of claim 16, wherein the circuit breaker is limited to the predetermined amount of current.

18. The system of claim 17, wherein to reach the voltage that triggers the dry input digital output to be a 1 at a certain current level of current flowing through the electrical circuit.

19. The system of claim 16, wherein the dry input contact with the isolated reading (input is analog, output is digital, can be 0 or 1).

20. The system of claim 16, wherein the microcontroller senses a dry input isolated output (0 or 1).
